(19) United States
(12) Patent Application Publication
(10) Pub. No.: US 2026/0129744 A1
(43) Pub. Date: May 7, 2026

(54) SUBSTRATE CONNECTION STRUCTURE, AND ANTENNA DEVICE AND COMMUNICATION DEVICE INCORPORATING SAME

(71) Applicant: Murata Manufacturing Co., Ltd., Nagaokakyo-shi (JP)

(72) Inventor: Yosuke SATO, Nagaokakyo-shi (JP)

(73) Assignee: Murata Manufacturing Co., Ltd., Nagaokakyo-shi (JP)

(21) Appl. No.: 19/428,376

(22) Filed: Dec. 22, 2025

Related U.S. Application Data
(63) Continuation of application No. PCT/JP2024/020922, filed on Jun. 7, 2024.

(30) Foreign Application Priority Data
Sep. 19, 2023 (JP) 2023-150980

(51) Int. Cl. H05K 1/02; H01Q 1/22; H01Q 9/04

(52) U.S. Cl. CPC H05K 1/0243; H01Q 1/22; H01Q 9/0407; H05K 2201/10098

(57) ABSTRACT

An opposing surface of a first substrate faces a side surface of a second substrate. The first substrate includes a first signal line, a first signal electrode, and a first ground electrode. The first ground electrode has an opening that surrounds the first signal electrode. The second substrate includes a second signal electrode, a second signal line, and a second ground electrode. The second ground electrode includes a first portion that overlaps the second signal electrode and a second portion that does not overlap the second signal electrode when viewed in an X-axis direction. A distance in the X-axis direction between the second signal electrode and the first portion is greater than a distance in the X-axis direction between the second signal line and the second portion.

### CROSS-REFERENCE TO RELATED APPLICATIONS

This application is a continuation of International Application No. PCT/JP2024/020922, filed on Jun. 7, 2024, which claims priority to Japanese Patent Application No. 2023-150980, filed on Sep. 19, 2023. The entire disclosures of the prior applications are hereby incorporated by reference in their entirety.

### TECHNICAL FIELD

The present disclosure relates to a substrate connection structure, and an antenna device and a communication device incorporating the same.

### BACKGROUND ART

International Publication No. 2020/170722 (Patent Document 1) discloses an antenna device including flat patch antennas (radiating elements). In this antenna device, the patch antenna are disposed in a substrate connection structure formed by connecting a first substrate and a second substrate having different normal directions from each other. The first substrate and the second substrate are connected to each other via a bent portion, and a ground electrode for the patch antennas and signal lines are disposed so as to extend across the first substrate, the bent portion, and the second substrate.

### CITATION LIST

### Patent Document

Patent Document 1: International Publication No. 2020/170722

### SUMMARY

### Technical Problems

In the antenna device disclosed in International Publication No. 2020/170722 (Patent Document 1), the first substrate and the second substrate, which have different normal directions, are connected to each other via a bent portion. Consequently, the bent portion becomes dead space and there are concerns about an increase in the size of the substrate connection structure. One possible way of reducing the area required for disposing the substrate connection structure is to eliminate the bent portion and connect a side surface of the second substrate to a main surface of the first substrate, and to dispose a ground electrode and a signal line across the first substrate and the second substrate. However, if the ground electrode and the signal line are simply disposed across the first and second substrates, there will be a problem in that impedance matching will be not easy.

The present disclosure has been made to solve the above-mentioned problems, and is directed to providing a substrate connection structure including a first substrate and a second substrate with different normal directions from each other that can be made small in size and configured to facilitate impedance matching.

### Solutions to Problems

A substrate connection structure according to the present disclosure includes a first substrate and a second substrate. The second substrate has a main surface and a side surface that intersect each other. The first substrate includes an opposing surface facing the side surface of the second substrate, a first signal line disposed opposite the opposing surface, a plate-shaped first ground electrode disposed on the opposing surface or disposed opposite the opposing surface at a position between the opposing surface and the first signal line, and a first signal electrode connected to the first signal line and exposed on the opposing surface. The second substrate includes a second signal line disposed opposite the main surface, a plate-shaped second ground electrode disposed opposite the main surface at a position between the main surface and the second signal line, and a second signal electrode connected to the second signal line and exposed on the side surface and connected to the first signal electrode. The first ground electrode is configured to sandwich the first signal electrode from at least two directions when viewed in a first direction that is normal to the opposing surface. The second ground electrode includes a first portion connected to the first ground electrode and a second portion connected to the first portion. When viewed in a second direction that is a normal direction of the main surface, at least part of the first portion overlaps the second signal electrode, and the second portion does not overlap the second signal electrode. A distance in the second direction between the second signal electrode and the first portion is greater than a distance in the second direction between the second signal line and the second portion.

An antenna device according to the present disclosure includes the above-described substrate connection structure.

A communication device according to the present disclosure includes the above-described substrate connection structure.

### Advantageous Effects

According to the present disclosure, a substrate connection structure including a first substrate and a second substrate having different normal directions from each other can be made small in size and configured to facilitate impedance matching.

### BRIEF DESCRIPTION OF DRAWINGS

FIG. 1 is an example of a block diagram of a communication device to which an antenna device including a substrate connection structure is applied.

FIG. 2 is a diagram illustrating a connection structure between a first substrate and a second substrate (No. 1).

FIG. 3 is a diagram illustrating simulation results of return loss (No. 1).

FIG. 4 is a diagram illustrating a connection structure between a first substrate and a second substrate (No. 2).

FIG. 5 is a diagram illustrating simulation results of return loss (No. 2).

FIG. 6 is a diagram illustrating a connection structure between a first substrate and a second substrate (No. 3).

FIG. 7 is a diagram illustrating simulation results of return loss (No. 3).

FIG. 8 is a diagram illustrating a connection structure between a first substrate and a second substrate (No. 4).

FIG. 9 is a diagram illustrating a connection structure between a first substrate and a second substrate (No. 5).

FIG. 10 is a diagram illustrating a connection structure between a first substrate and a second substrate (No. 6).

FIG. 11 is a diagram illustrating a perspective view of a first substrate (No. 1).

FIG. 12 is a diagram illustrating a perspective view of a first substrate (No. 2).

FIG. 13 is a diagram illustrating a perspective view of a first substrate (No. 3).

### DESCRIPTION OF EMBODIMENTS

Hereinafter, embodiments of the present disclosure will be described in detail with reference to the drawings. In the drawings, the same or corresponding parts are denoted by the same reference symbols, and description thereof is not repeated.

### Basic Configuration of Communication Device

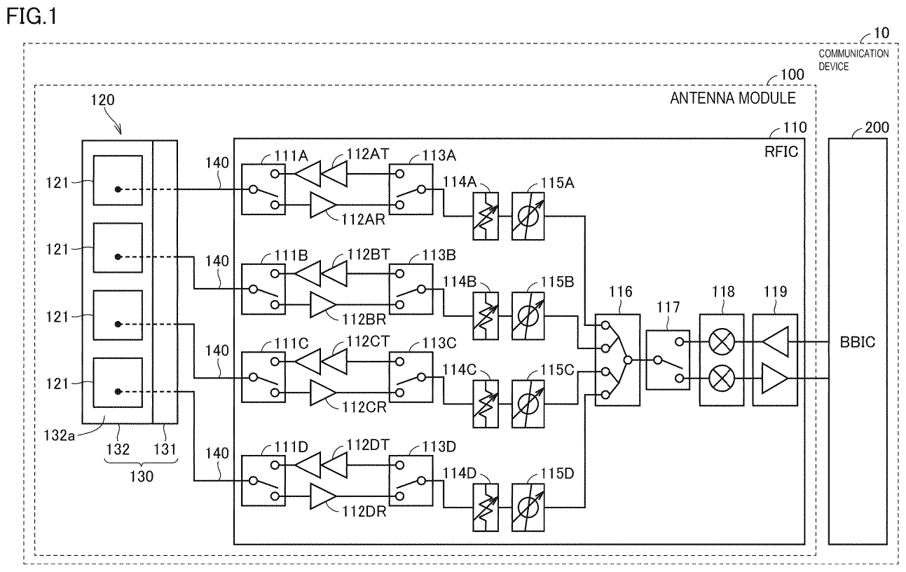

FIG. 1 is an example of a block diagram of a communication device 10 to which an antenna device 120 including a substrate connection structure according to this embodiment is applied. The communication device 10 is, for example, a mobile terminal such as a mobile phone, smartphone, or tablet, or a personal computer having a communication function. An example of the frequency band of radio waves used in the antenna device 120 according to this embodiment is millimeter-wave radio waves with center frequencies of 28 GHz, 39 GHz, and 60 GHz, but radio waves in other frequency bands are also applicable.

Referring to FIG. 1, the communication device 10 includes an antenna module 100 and a BBIC 200 that constitutes a baseband signal processing circuit. The antenna module 100 includes an RFIC 110, which is an example of a power feeding device, and the antenna device 120. The communication device 10 up converts an intermediate-frequency signal transmitted from the BBIC 200 to the antenna module 100 into a high-frequency signal and radiates the high-frequency signal from the antenna device 120, and also down converts a high-frequency signal received by the antenna device 120 into an intermediate-frequency signal and processes the signal in the BBIC 200.

The antenna device 120 includes a dielectric substrate 130 on which a plurality of radiating elements 121 are disposed. Each radiating element 121 is a patch antenna shaped like a flat plate. The dielectric substrate 130 is a substrate connection structure including a first substrate 131 and a second substrate 132 connected to each other in a state where their normal directions are different from each other. The first substrate 131 and the second substrate 132 both have a flat plate-like shape. The plurality of radiating elements 121 are disposed on a first main surface 132a of the second substrate 132.

FIG. 1 illustrates an example of an array configuration in which four radiating elements 121 are disposed in a line, but the number and arrangement of the radiating elements 121 are not limited to this example. A single radiating element 121 may be disposed on first main surface 132a of second substrate 132, or five or more radiating elements 121 may be disposed. In addition, an array configuration in which the radiating elements 121 are disposed in a two-dimensional manner may be adopted.

The first substrate 131 and the second substrate 132 may each be, for example, a low-temperature co-fired ceramics (LTCC) multilayer substrate, a multilayer resin substrate formed by stacking multiple resin layers composed of a resin such as epoxy or polyimide, a multilayer resin substrate formed by stacking multiple resin layers composed of a liquid crystal polymer (LCP) having a lower dielectric constant, a multilayer resin substrate formed by stacking multiple resin layers composed of a fluorine-based resin, a multilayer resin substrate formed by stacking multiple resin layers composed of polyethylene terephthalate (PET), or a ceramic multilayer substrate other than a LTCC. The first substrate 131 and the second substrate 132 do not necessarily have a multilayer structure and may be single-layer substrates. The first substrate 131 and the second substrate 132 may be formed of the same dielectric material or different dielectric materials.

In the antenna module 100 according to this embodiment, a high-frequency signal is supplied to each radiating element 121 from corresponding feed wiring 140. The antenna module 100 is a so-called single-band single-polarization type antenna module.

The RFIC 110 includes switches 111A to 111D, 113A to 113D, and 117, power amplifiers 112AT to 112DT, low-noise amplifiers 112AR to 112DR, attenuators 114A to 114D, phase shifters 115A to 115D, a signal combiner/divider 116, a mixer 118, and an amplifier circuit 119.

When a high-frequency signal is to be transmitted, the switches 111A to 111D and 113A to 113D are switched to the side of the power amplifiers 112AT to 112DT, and the switch 117 is connected to the transmission amplifier of the amplifier circuit 119. When a high-frequency signal is to be received, the switches 111A to 111D and 113A to 113D are switched to the side of the low-noise amplifiers 112AR to 112DR, and the switch 117 is connected to the reception amplifier of the amplifier circuit 119.

An intermediate frequency signal transmitted from BBIC 200 is amplified by amplifier circuit 119 and up-converted by the mixer 118. The up-converted high-frequency signal, that is, the transmission signal is split into four signals by signal combiner/divider 116, the signals pass along the corresponding signal paths, and are fed to different radiating elements 121. By individually adjusting the phase shift of phase shifters 115A to 115D disposed on the individual signal paths, it is possible to adjust the directivity of the radio waves output from radiating elements 121. In addition, the attenuators 114A to 114D adjust the strength of the transmission signal.

Reception signals, which are high-frequency signals received by the individual radiating elements 121, are transmitted to the RFIC 110, pass along four different signal paths, and are combined in the signal combiner/divider 116. The combined reception signal is down-converted to an intermediate-frequency signal in the mixer 118, and further amplified in the amplifier circuit 119 before being transmitted to the BBIC 200.

The RFIC 110 is formed, for example, as a one-chip integrated circuit component. Alternatively, devices (switch, power amplifier, low-noise amplifier, attenuator, phase shifter) corresponding to each radiating element may be formed as a one-chip integrated circuit component for each corresponding radiating element. The RFIC 110 may also be mounted on the first substrate 131 of the antenna device 120.

### Configuration of Dielectric Substrate 130

Next, the configuration of dielectric substrate 130 will be described. As described above, this is a substrate connection structure including the first substrate 131 and the second substrate 132 connected to each other in a state where their normal directions are different from each other.

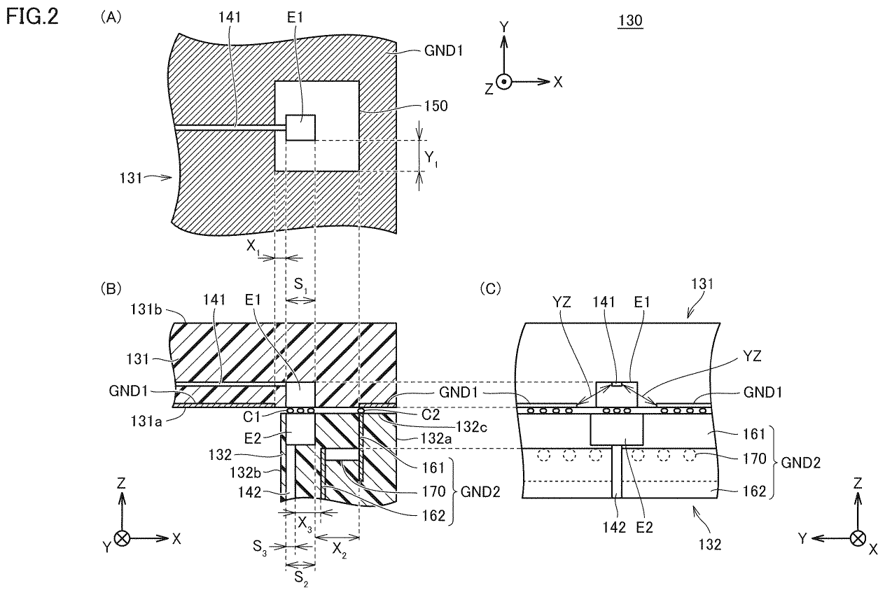

FIG. 2 is a diagram partially illustrating the connection structure between the first substrate 131 and the second substrate 132 in the dielectric substrate 130. The upper left part (A) of FIG. 2 illustrates a perspective view of the first substrate 131, the lower left part (B) of FIG. 2 illustrates a cross-sectional view of a connection portion between the first substrate 131 and the second substrate 132, and the lower right part (C) of FIG. 2 illustrates a perspective view of the connection portion between first substrate 131 and second substrate 132.

The first substrate 131 has an opposing surface 131a that faces the second substrate 132, and a main surface 131b that is on the opposite side from the opposing surface 131a.

The second substrate 132 has the first main surface 132a, a second main surface 132b on the opposite side from the first main surface 132a, and a side surface 132c substantially perpendicular to the first main surface 132a and the second main surface 132b. The side surface 132c of the second substrate 132 faces the opposing surface 131a of the first substrate 131.

The normal direction of the opposing surface 131a of the first substrate 131 and the normal direction of the first main surface 132a of the second substrate 132 are substantially perpendicular to each other. The dielectric substrate 130, which is a substrate connection structure including the first substrate 131 and the second substrate 132, is shaped like the letter L.

In the following description, the normal direction of the opposing surface 131a of the first substrate 131 is defined as a Z-axis direction, the normal direction of the first main surface 132a of the second substrate 132 is defined as an X-axis direction, and a direction perpendicular to the Z-axis direction and the X-axis direction is defined as a Y-axis direction. In addition, the positive direction of the Z-axis in each drawing may be referred to as upward, and the negative direction may be referred to downward.

The first substrate 131 includes a first ground electrode GND1, a first signal line 141, and a first signal electrode E1.

The first ground electrode GND1 is disposed on the opposing surface 131a and extends in a plate-like shape along the opposing surface 131a. The first ground electrode GND1 may be disposed at a position (layer) between the opposing surface 131a and the first signal line 141. As illustrated in (A) of FIG. 2, the first ground electrode GND1 includes an opening 150 that opens so as to surround the first signal electrode E1 when viewed in the Z-axis direction.

The first signal line 141 is disposed opposite the opposing surface 131a and extends linearly in the X-axis direction.

The first signal electrode E1 is a conductor having a substantially rectangular parallelepiped shape and is for connecting the first signal line 141 to outside the first substrate 131. As illustrated in (A) of FIG. 2, the first signal electrode E1 is disposed at a position (i.e., an area inside the opening 150) that does not overlap the first ground electrode GND1 when viewed in the Z-axis direction. As illustrated in (B) of FIG. 2, the upper surface of the first signal electrode E1 is connected to a tip portion of the first signal line 141. The lower surface of the first signal electrode E1 is exposed at the opposing surface 131a and is connected to the upper surface of a second signal electrode E2 via solder bumps C1.

The second substrate 132 includes a second signal line 142, the second signal electrode E2, and a second ground electrode GND2.

The second signal line 142 is disposed opposite the first main surface 132a and extends linearly in the Z-axis direction.

The second signal electrode E2 is a conductor having a substantially rectangular parallelepiped shape and is for connecting the second signal line 142 to outside the second substrate 132. The lower surface of the second signal electrode E2 is connected to a tip portion of the second signal line 142. A size S₂ of the second signal electrode E2 in the X-axis direction is larger than a size S₃ of the second signal line 142 in the X-axis direction. A size S₁ of the first signal electrode E1 in the X-axis direction is substantially the same as the size S₂ of the second signal electrode E2 in the X-axis direction.

The upper surface of the second signal electrode E2 is exposed at the side surface 132c and is connected to the lower surface of the first signal electrode E1 via solder bumps C1.

The combination of the first signal line 141, the first signal electrode E1, the second signal electrode E2, and the second signal line 142 functions as a single feed wiring 140 (see FIG. 1) that is disposed across the first substrate 131 and the second substrate 132.

The second ground electrode GND2 is disposed at a position (layer) between the first main surface 132a and the second signal line 142. The second ground electrode GND2 includes a first portion 161, a second portion 162, and a connection conductor 170 such as a via.

The first portion 161 extends in a plate-like shape parallel to the first main surface 132a. The upper end of the first portion 161 is exposed at the side surface 132c and is connected to the first ground electrode GND1 via solder bumps C2. Therefore, the combination of the first ground electrode GND1 and the second ground electrode GND2 functions as a ground electrode for the feed wiring 140 that is disposed across the first substrate 131 and the second substrate 132.

The second portion 162 is disposed at a position (layer) between the first portion 161 and the second signal line 142, and extends in a plate-like shape parallel to the first portion 161. The upper end of the second portion 162 is connected to the first portion 161 via the connection conductor 170. The upper end of the second portion 162 is disposed at a position lower than the lower end of the second signal electrode E2 in the Z-axis direction. That is, as illustrated in (C) of FIG. 2, when the second ground electrode GND2 is viewed in the X-axis direction, the first portion 161 includes a portion overlapping the second signal electrode E2, but the second portion 162 does not include a portion overlapping the second signal electrode E2.

A distance X₂ between the second signal electrode E2 and the first portion 161 in the X-axis direction is greater than a distance X₃ between the second signal line 142 and the second portion 162 in the X-axis direction. This stepped-distance relationship (where X2>X3) may serve to manage the impedance transition from the second signal line 142 to the second signal electrode E2.

The distance X₂ between the second signal electrode E2 and the first portion 161 in the X-axis direction, a shortest distance X₁ between the first signal electrode E1 and the inner wall of the opening 150 in the X-axis direction, and a distance Y₁ between the first signal electrode E1 and the inner wall of the opening 150 in the Y-axis direction satisfy the following Formula (1).

0.5X₂<Y₁<2X₂ and X₁<Y₁ . . . (1)

That is, the distance Y₁ is greater than half the distance X₂ and greater than the distance X₁, and is less than twice the distance X₂.

In the dielectric substrate 130 having the above-described configuration, when connecting the first substrate 131 and the second substrate 132 to each other, the opposing surface 131a of the first substrate 131 and the side surface 132c of the second substrate 132 are connected via the solder bumps C1 and C2. Therefore, compared to when the first substrate 131 and the second substrate 132 are connected to each other via a bent portion, no space is required in which to dispose a bent portion, and the dielectric substrate 130 can be reduced in size by a corresponding amount.

Furthermore, in the dielectric substrate 130, when transmitting a signal to the feed wiring 140 (the combination of the first signal line 141, the first signal electrode E1, the second signal electrode E2, and the second signal line 142) disposed across the first substrate 131 and the second substrate 132, impedance matching can be achieved at each of the following (1) to (5).
(1) A first microstrip line formed by coupling between the first signal line 141 and the first ground electrode GND1.
(2) A first coplanar line (distance YZ between the first signal line 141 and the inner wall of the opening 150 in the Y-axis direction) formed by coupling between the first signal line 141 and the inner wall of the opening 150 in the Y-axis direction in the opening 150 of the first ground electrode GND1.
(3) A second coplanar line (distance Y₁) formed by coupling between the first signal electrode E1 and the inner wall of the opening 150 in the Y-axis direction in the opening 150 of the first ground electrode GND1.
(4) A second microstrip line (distance X₂) formed by coupling between the second signal electrode E2 and the first portion 161 of the second ground electrode GND2.
(5) A third microstrip line (distance X₃) formed by coupling between the second signal line 142 and the second portion 162 of the second ground electrode GND2.

For example, when transmitting a signal from the first signal line 141 to the second signal line 142, the signal transmission line is sequentially transformed from the first microstrip line to the first coplanar line and the second coplanar line, the second microstrip line, and the third microstrip line.

Therefore, impedance matching can be achieved by adjusting not only the transmission characteristics of the first microstrip line, but also the transmission characteristics of the first coplanar line (distance YZ), the transmission characteristics of the second coplanar line (distance Y₁), the transmission characteristics of the second microstrip line (distance X₂), and the transmission characteristics of the third microstrip line (distance X₃).

As a result, impedance matching can be achieved easily. This multi-stage approach provides the designer with significantly more variables to tune the connection for optimal performance across a wide frequency band.

In particular, in this embodiment, the distance Y₁ between the first signal electrode E1 and the inner wall of the opening 150 in the Y-axis direction is set in a range that is larger than half (=0.5×X₂) of the distance X₂ between the second signal electrode E2 and the first portion 161 in the X-axis direction, is larger than the shortest distance X₁ between the first signal electrode E1 and the inner wall of the opening 150 in the X-axis direction, and is smaller than twice the distance X₂. Setting the distance Y₁ in this way makes it easier to achieve impedance matching.

Furthermore, the size S₂ of the second signal electrode E2 in the X-axis direction is larger than the size S₃ of the second signal line 142 in the X-axis direction. Therefore, even if some amount of misalignment occurs in the X-axis direction when the second substrate 132 is mounted on the first substrate 131, the second signal electrode E2 can be properly connected to the first signal electrode E1.

Furthermore, by making the size S₂ of the second signal electrode E2 in the X-axis direction larger than the size S₃ of the second signal line 142 in the X-axis direction, it is possible to reduce return loss.

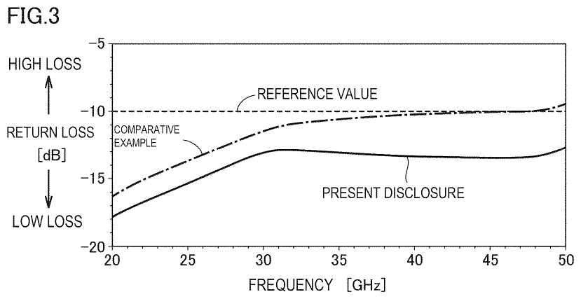

FIG. 3 is a diagram illustrating an example of simulation results of return loss obtained when a signal is transmitted using the feed wiring 140 of the dielectric substrate 130 according to this embodiment. In FIG. 3, the horizontal axis represents frequency (GHz) and the vertical axis represents return loss. Return loss is expressed in decibels (dB) as the ratio of reflected power to input power. Therefore, return loss is 0 dB when the reflectivity is 100% (total reflection), and has a negative value when the reflectivity is less than 100% (partial reflection). The smaller the amount of reflection, the smaller the value of return loss (the larger the negative absolute value).

In FIG. 3, the results obtained when using dielectric substrate 130 according to this embodiment are illustrated by a solid line, and the results obtained when using the configuration of a comparative example are illustrated by a dash dot line. The configuration of the comparative example is a configuration in which the dielectric substrate 130 according to this embodiment is modified so that the distance X₂ and the distance X₃ have the same value.

As can be seen from FIG. 3, when the dielectric substrate 130 according to this embodiment is used, the return loss can be suppressed to a value lower than a reference value (minus 10 dB) across the entire simulated frequency range (20 to 50 GHz), which is a favorable result.

Furthermore, the results show that the return loss when using the dielectric substrate 130 according to this embodiment was lower than the return loss when using the configuration of the comparative example across the entire simulated frequency range (20 to 50 GHz). This result is thought to be due to the fact that the distance X₂ and the distance X₃ have the same value in the configuration of the comparative example, whereas the distance X₂ is greater than the distance X₃ in the dielectric substrate 130 according to this embodiment.

The “first substrate 131” and the “second substrate 132” according to this embodiment may respectively correspond to the “first substrate” and the “second substrate”of the present disclosure.

The “first signal line 141” and the “first signal electrode E1” according to the present embodiment may correspond to the “first signal line” and the “first signal electrode” of the present disclosure, respectively.

The “first ground electrode GND1” and the “opening 150” according to this embodiment may respectively correspond to the “first ground electrode” and the “opening” of the present disclosure.

The “second signal electrode E2” and the “second signal line 142” according to this embodiment may respectively correspond to the “second signal electrode” and the “second signal line” of the present disclosure.

The “second ground electrode GND2”, “first portion 161”, “second portion 162”, and “connection conductor 170” according to this embodiment may respectively correspond to the “second ground electrode”, “first portion”, “second portion”, and “connection conductor” of the present disclosure.

The “Z-axis direction” and “X-axis direction” according to this embodiment may correspond to the “first direction” and “second direction”of the present disclosure.

The “distance X₁”, “distance X₂”, and “distance Y₁” according to this embodiment may correspond to the “first distance”, “second distance”, and “third distance” of the present disclosure.

### [Modification 1]

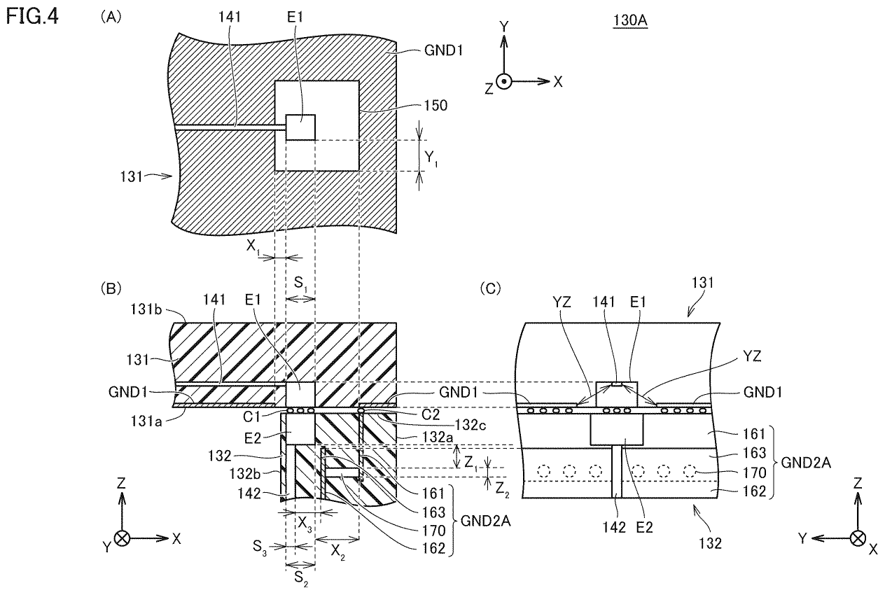

FIG. 4 is a diagram partially illustrating a connection structure between the first substrate 131 and the second substrate 132 in a dielectric substrate 130A according to Modification 1. In the dielectric substrate 130A according to Modification 1, the second ground electrode GND2 of dielectric substrate 130 described above is changed to a second ground electrode GND2A. The upper left part (A) of FIG. 4 illustrates a perspective view of the first substrate 131, the lower left part (B) of FIG. 4 illustrates a cross-sectional view of a connection portion between the first substrate 131 and the second substrate 132, and the lower right part (C) of FIG. 4 illustrates a perspective view of the connection portion between first substrate 131 and second substrate 132.

The second ground electrode GND2A is obtained by adding a third portion 163 to the above-described second ground electrode GND2. That is, the second ground electrode GND2A includes the third portion 163 in addition to the first portion 161, the second portion 162, and the connection conductor 170.

The third portion 163 extends in a plate-like shape from the upper end of the second portion 162 (the connection portion between the second portion 162 and the connection conductor 170) in the positive direction of the Z axis (toward the side surface 132c).

A distance Z₁ between the connection conductor 170 and the second signal electrode E2 in the Z-axis direction is larger than a size Z₂ of the connection conductor 170 in the Z-axis direction.

With this configuration, impedance matching can be easily achieved even when the connection conductor 170 is formed of a via. Specifically, when the connection conductor 170 is formed of a via, a certain amount of area is required for the connection portion between the second portion 162 and the via. However, in the second ground electrode GND2A according to Modification 1, the distance Z1 between the connection conductor 170 and the second signal electrode E2 in the Z-axis direction is larger than the size Z2 of the connection conductor 170 in the Z-axis direction, and therefore, the area required for the connection between the second portion 162 and the via can be secured.

Furthermore, as a result of the second ground electrode GND2A according to Modification 1 including the third portion 163, impedance disturbances caused by the difference between the distance X₂ in the X-axis direction between the second signal electrode E2 and the first portion 161 and the distance X₃ in the X-axis direction between the second signal line 142 and the second portion 162 can be adjusted, thereby facilitating impedance matching.

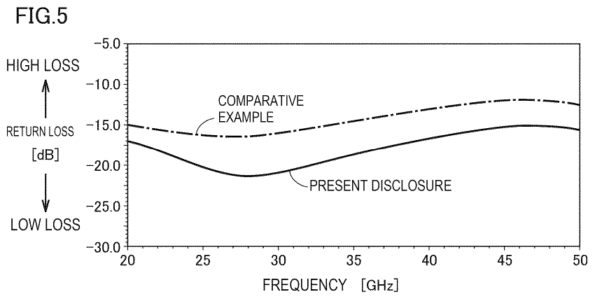

FIG. 5 is a diagram illustrating an example of the simulation results of the return loss when a signal is transmitted using the feed wiring 140 of the dielectric substrate 130A according to Modification 1. In FIG. 5, the results obtained when the dielectric substrate 130A according to Modification 1 is used are represented by a solid line, and the results obtained when the configuration of the comparative example is used are represented by a dash dot line. The configuration of the comparative example is a configuration in which the third portion 163 is omitted from the dielectric substrate 130A according to Modification 1.

As can be seen from FIG. 5, the return loss when the dielectric substrate 130A according to Modification 1 is used is reduced compared to the return loss when the configuration of the comparative example is used.

The “second ground electrode GND2A” according to Modification 1 may correspond to the “second ground electrode” of the present disclosure.

### [Modification 2]

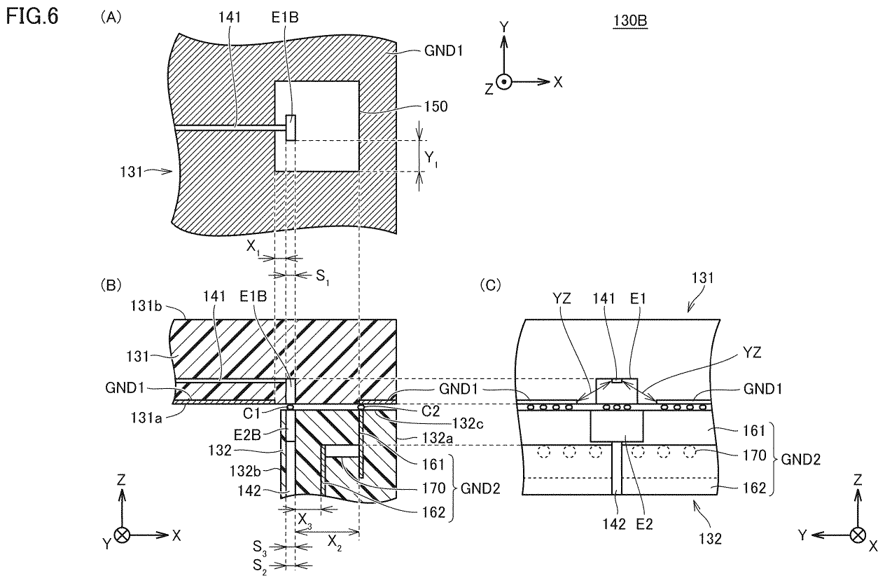

FIG. 6 is a diagram partially illustrating the connection structure between the first substrate 131 and the second substrate 132 in a dielectric substrate 130B according to Modification 2. In the dielectric substrate 130B according to Modification 2, the first signal electrode E1 and the second signal electrode E2 of the above-described dielectric substrate 130 are changed to a first signal electrode E1B and a second signal electrode E2B, respectively. The upper left part (A) of FIG. 6 illustrates a perspective view of the first substrate 131, the lower left part (B) of FIG. 6 illustrates a cross-sectional view of a connection portion between the first substrate 131 and the second substrate 132, and the lower right part (C) of FIG. 6 illustrates a perspective view of the connection portion between first substrate 131 and second substrate 132.

A size S₂ of the second signal electrode E2B in the X-axis direction is substantially the same as the size S₃ of the second signal line 142 in the X-axis direction. A size S₁ of the first signal electrode E1B in the X-axis direction is substantially the same as the size S₂ of the second signal electrode E2 in the X-axis direction.

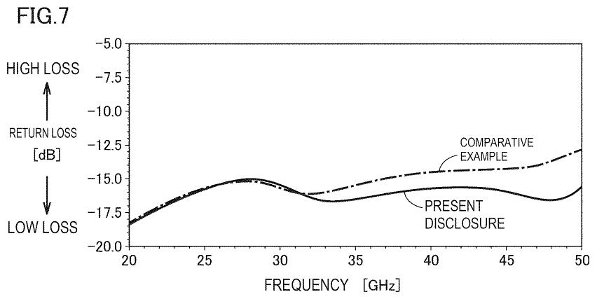

FIG. 7 is a diagram illustrating an example of the simulation results of the return loss obtained when a signal is transmitted using the feed wiring 140 of the dielectric substrate 130B according to Modification 2. In FIG. 7, the results obtained when the dielectric substrate 130B according to Modification 2 is used are represented by a solid line, and the results when the configuration of the comparative example is used are represented by a dash dot line. The configuration of the comparative example is a configuration in which the dielectric substrate 130B according to Modification 2 is modified so that the distance X₂ and the distance X₃ have the same value.

As can be seen from FIG. 7, the return loss obtained when the dielectric substrate 130B according to Modification 2 is used is reduced compared to the return loss when the configuration of the comparative example is used.

The “first signal electrode E1B” and the “second signal electrode E2B” according to Modification 2 may correspond to the “first signal electrode” and the “second signal electrode” of the present disclosure, respectively.

### [Modification 3]

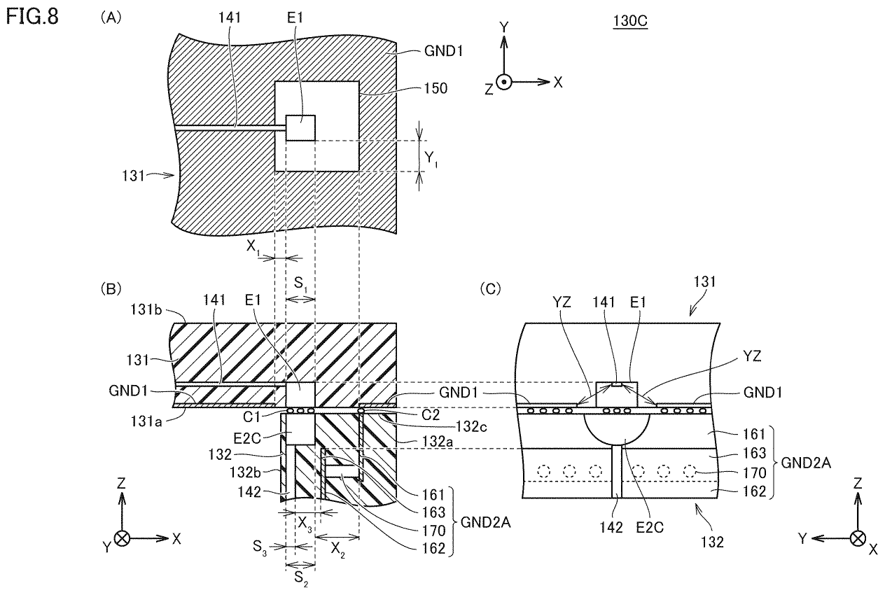

FIG. 8 is a diagram partially illustrating the connection structure between the first substrate 131 and the second substrate 132 in a dielectric substrate 130C according to Modification 3. In the dielectric substrate 130C according to Modification 3, the second signal electrode E2 of the dielectric substrate 130A according to Modification 1 described above is changed to a second signal electrode E2C. The upper left part (A) of FIG. 8 illustrates a perspective view of the first substrate 131, the lower left part (B) of FIG. 8 illustrates a cross-sectional view of a connection portion between the first substrate 131 and the second substrate 132, and the lower right part (C) of FIG. 8 illustrates a perspective view of the connection portion between first substrate 131 and second substrate 132.

The second signal electrode E2C is a conductor having a semi-cylindrical shape when viewed in the X-axis direction. Thus, the shape of the second signal electrode E2C is not limited to a rectangular parallelepiped shape, and may be a semi-cylindrical shape.

The “second signal electrode E2C” according to Modification 3 may correspond to the “second signal electrode” of the present disclosure.

### [Modification 4]

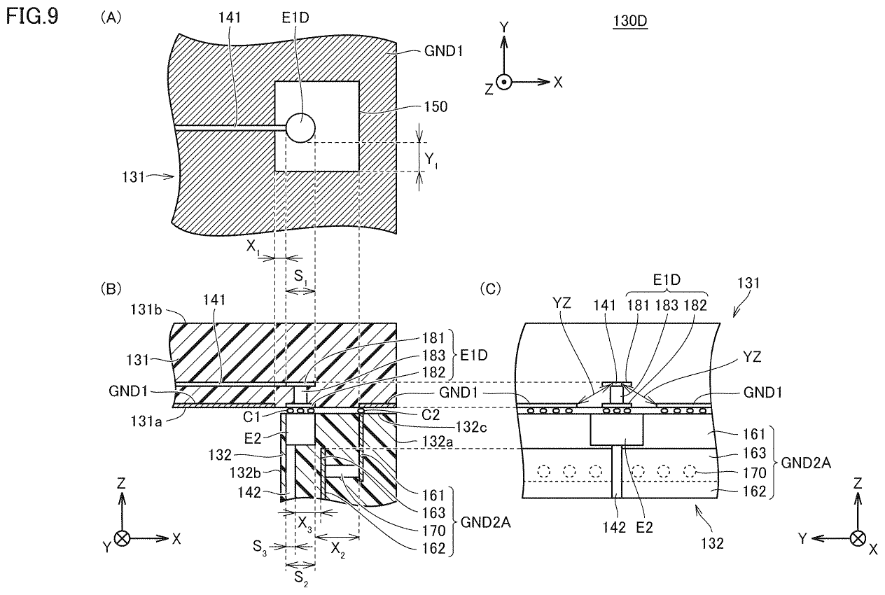

FIG. 9 is a diagram partially illustrating the connection structure between the first substrate 131 and the second substrate 132 in a dielectric substrate 130D according to Modification 4. In the dielectric substrate 130D according to Modification 4, the first signal electrode E1 of the dielectric substrate 130A according to Modification 1 described above is changed to a first signal electrode E1D. The upper left part (A) of FIG. 9 illustrates a perspective view of the first substrate 131, the lower left part (B) of FIG. 9 illustrates a cross-sectional view of a connection portion between the first substrate 131 and the second substrate 132, and the lower right part (C) of FIG. 9 illustrates a perspective view of the connection portion between first substrate 131 and second substrate 132.

The first signal electrode E1D includes a first pad 181, a second pad 182, and a connection conductor 183.

The first pad 181 is connected to a tip portion of the first signal line 141. The second pad 182 is exposed at the opposing surface 131a and is connected to the upper surface of the second signal electrode E2 via solder bumps C1. The first pad 181 and the second pad 182 are connected to each other by a connection conductor 183 such as a via.

Thus, the shape of the first signal electrode E1D is not limited to a rectangular parallelepiped shape, and may be a shape in which two pads on upper and lower sides are connected to each other by a via or the like.

The “first signal electrode E1D” according to Modification 4 may correspond to the “first signal electrode” of the present disclosure.

### [Modification 5]

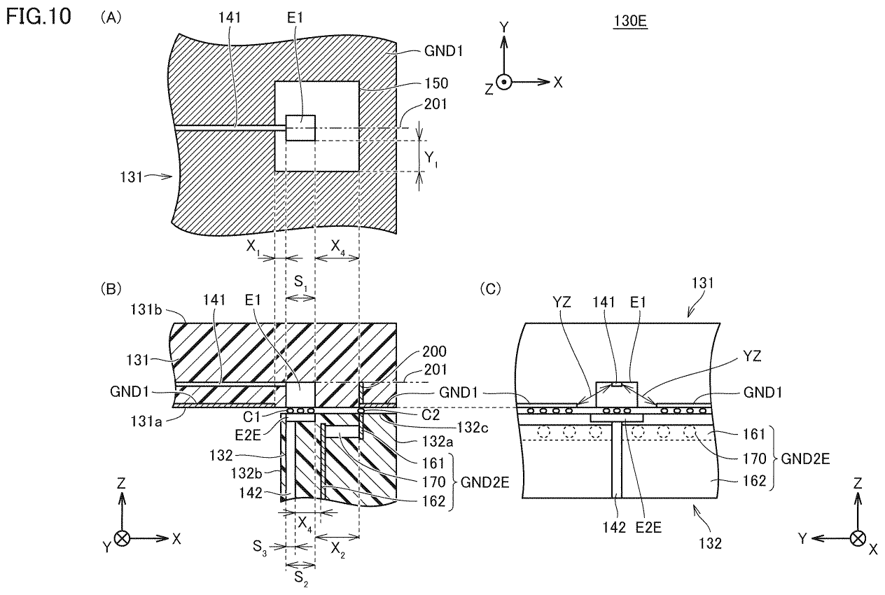

FIG. 10 is a diagram partially illustrating the connection structure between the first substrate 131 and the second substrate 132 in a dielectric substrate 130E according to Modification 5. The dielectric substrate 130E according to Modification 5 is obtained by adding a specific portion 200 to the first substrate 131 according to the above-described embodiments, and by changing the second signal electrode E2 and the second ground electrode GND2 according to the above-described embodiments to a second signal electrode E2E and a second ground electrode GND2E, respectively. The upper left part (A) of FIG. 10 illustrates a perspective view of the first substrate 131, the lower left part (B) of FIG. 10 illustrates a cross-sectional view of a connection portion between the first substrate 131 and the second substrate 132, and the lower right part (C) of FIG. 10 illustrates a perspective view of the connection portion between first substrate 131 and second substrate 132.

The specific portion 200 is a flat-plate-shaped ground electrode that extends from the inner wall of the opening 150 in the positive direction of the Z axis (toward an imaginary line 201) at a position where the imaginary line 201 overlaps the inner wall of the opening 150 of the first ground electrode GND1 when viewed in the Z axis direction when the imaginary line 201 (two-dot chain line) is drawn from the tip of the first signal line 141 in the extension direction of the first signal line 141.

A distance X₄ between the first signal electrode E1 and the specific portion 200 in the X-axis direction is substantially equal to the distance X₂ between the second signal electrode E2 and the first portion 161 in the X-axis direction.

The second signal electrode E2E is smaller in size in the Z-axis direction than the above-described second signal electrode E2. Accordingly, the position of the connection conductor 170 of the second ground electrode GND2E is shifted upward (in the positive direction of the Z-axis) relative to the position of the connection conductor 170 of the above-described second ground electrode GND2.

In the dielectric substrate 130E according to Modification 5, in addition to (1) to (5) described in the above embodiment, (1-1) impedance matching can be achieved in a fourth microstrip line (distance X₄) formed by coupling between the first signal electrode E1 and the specific portion 200. That is, in the dielectric substrate 130E according to Modification 5, impedance matching can be achieved in each of the following: (1), (1E), (2), (3), (4), and (5).
(1) The first microstrip line.
(1-1) The fourth microstrip line (distance X₄) formed by coupling between the first signal electrode E1 and the specific portion 200. In Modification 5, impedance matching using this fourth microstrip line (distance X₄) is added to the above-described embodiment.
(2) The first coplanar line (distance YZ).
(3) The second coplanar line (distance Y₁).
(4) The second microstrip line (distance X₂).
(5) The third microstrip line (distance X₃).

For example, when transmitting a signal from the first signal line 141 to the second signal line 142, the signal transmission line is sequentially transformed from the first microstrip line to the fourth microstrip line, the first coplanar line and the second coplanar line, the second microstrip line, and the third microstrip line.

Therefore, impedance matching can be achieved by adjusting not only the transmission characteristics of the first microstrip line, but also the transmission characteristics of the fourth microstrip line (distance X₄), the transmission characteristics of the first coplanar line (distance YZ), the transmission characteristics of the second coplanar line (distance Y₁), the transmission characteristics of the second microstrip line (distance X₂), and the transmission characteristics of the third microstrip line (distance X₃). As a result, impedance matching can be achieved more easily.

Furthermore, in Modification 5, the distance X₄ between the first signal electrode E1 and the specific portion 200 in the X-axis direction is substantially equal to the distance X₂ between the second signal electrode E2 and the first portion 161 in the X-axis direction. Therefore, the part of the impedance matching that was handled by the second microstrip line (distance X₂) formed in the second substrate 132 can be transferred to the fourth microstrip line (distance X₄) formed in the first substrate 131. As a result, in Modification 5, the size of the second signal electrode E2E in the Z-axis direction can be made smaller than the size of the above-described second signal electrode E2 in the Z-axis direction, and accordingly, the position of the connection conductor 170 in the Z-axis direction can be shifted upward. As a result, the size of the second substrate 132 in the Z-axis direction can be reduced.

The “specific portion 200”, the “second signal electrode E2E”, and the “second ground electrode GND2E” according to Modification 5 may respectively correspond to the “specific portion”, the “second signal electrode”, and the “second ground electrode” of the present disclosure.

### [Modification 6]

FIG. 11 is a diagram illustrating a perspective view of the first substrate 131 according to Modification 6. In the first substrate 131 according to Modification 6, a plurality of combinations of the first signal line 141, the first signal electrode E1, and the opening 150 are disposed side by side in the Y-axis direction.

That is, in Modification 6, a single feed wiring 140 (first signal line 141 and first signal electrode E1) passes through one opening 150. Therefore, the size Y2 of each opening 150 in the Y-axis direction is less than half a distance Y3 between two adjacent first signal lines 141 in the Y-axis direction.

Thus, a plurality of feed wiring 140 can be disposed while maintaining isolation characteristics between the feed wiring 140. As a result, an array configuration in which a plurality of radiating elements 121 are disposed can be accommodated on the second substrate 132. A configuration in which dual-band or dual-polarized radiating elements are disposed can also be accommodated on the second substrate 132.

### [Modification 7]

In the above-described embodiment, when the first signal electrode E1 is viewed in the Z-axis direction, the periphery of the first signal electrode E1 is entirely surrounded by the first ground electrode GND1. That is, the first signal electrode E1 is surrounded by the first ground electrode GND1 from four directions (the positive X-axis direction, the negative X-axis direction, the positive Y-axis direction, and the negative Y-axis direction).

However, when viewed in the Z-axis direction, the first signal electrode E1 does not necessarily need to be surrounded by the first ground electrode GND1 from four directions, and only needs to be sandwiched by the first ground electrode GND1 from at least two directions.

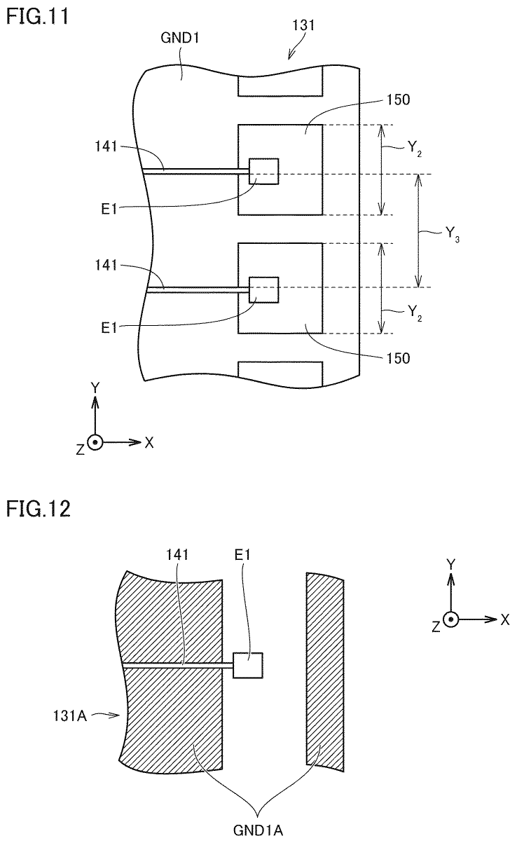

FIG. 12 is a diagram illustrating a perspective view of a first substrate 131A according to an example of Modification 7. In the first substrate 131A, the first ground electrode GND1 of the first substrate 131 described above is replaced with a first ground electrode GND1A. As illustrated in FIG. 12, the first ground electrode GND1A is divided into a portion disposed in the negative X-axis direction relative to the first signal electrode E1 and a portion disposed in the positive X-axis direction relative to the first signal electrode E1, and is configured so that the first signal electrode E1 is sandwiched between these two divided portions. Substantially the same effects as those of the above-described embodiment can also be achieved with the thus-configured first ground electrode GND1A.

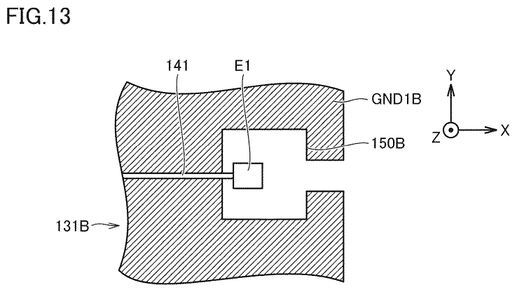

FIG. 13 is a diagram illustrating a perspective view of a first substrate 131B according to another example of Modification 7. In the first substrate 131B, the first ground electrode GND1 of the first substrate 131 described above is replaced with a first ground electrode GND1B. As illustrated in FIG. 13, the first ground electrode GND1B has an opening 150B that opens so as to surround the periphery of the first signal electrode E1, but a portion of the part surrounding the first signal electrode E1 from the positive X-axis direction side has been cut out. In other words, the opening 150B opens so as to surround the periphery of the first signal electrode E1 in at least three directions (the negative X-axis direction, the positive Y-axis direction, and the negative Y-axis direction). Substantially the same effects as those of the above-described embodiment can also be achieved with the thus-configured first ground electrode GND1B.

The embodiments disclosed herein should be considered as being illustrative in all aspects and not restrictive. The scope of the present invention is defined by the claims, not by the description of the above embodiments, and it is intended that equivalents to the scope of the claims and all modifications within the scope of the claims be included within the scope of the present invention.

It is to be understood by those skilled in the art that the above-described embodiments and the modifications thereof are specific examples of the following aspects.
(Item 1) A substrate connection structure according to the present disclosure includes a first substrate and a second substrate. The second substrate has a main surface and a side surface that intersect each other. The first substrate includes an opposing surface facing the side surface of the second substrate, a first signal line disposed opposite the opposing surface, a plate-shaped first ground electrode disposed on the opposing surface or disposed opposite the opposing surface at a position between the opposing surface and the first signal line, and a first signal electrode connected to the first signal line and exposed on the opposing surface. The second substrate includes a second signal line disposed opposite the main surface, a plate-shaped second ground electrode disposed opposite the main surface at a position between the main surface and the second signal line, and a second signal electrode connected to the second signal line and exposed on the side surface and connected to the first signal electrode. The first ground electrode is configured to sandwich the first signal electrode from at least two directions when viewed in a first direction that is normal to the opposing surface. The second ground electrode includes a first portion connected to the first ground electrode and a second portion connected to the first portion. When viewed in a second direction that is a normal direction of the main surface, at least part of the first portion overlaps the second signal electrode, and the second portion does not overlap the second signal electrode. A distance in the second direction between the first signal electrode and the first portion is greater than a distance in the second direction between the second signal line and the second portion.
(Item 2) In the substrate connection structure according to Item 1, a size of the second signal electrode in the second direction is larger than a size of the second signal line in the second direction.
(Item 3) In the substrate connection structure according to Item 1 or 2, the second ground electrode further includes a connection conductor extending in the second direction and connecting the first portion to the second portion, and a third portion extending in the first direction from the connection portion between the connection conductor and the second portion. A distance in the first direction between the connection conductor and the second signal electrode is greater than a size of the connection conductor in the first direction.
(Item 4) In the substrate connection structure according to Item 1 or 2, the second signal electrode has a rectangular parallelepiped shape or a semi-cylindrical shape.
(Item 5) In the substrate connection structure according to Item 1 or 2, the first ground electrode has an opening that opens so as to surround the first signal electrode when viewed in the first direction. When a shortest distance between the first signal electrode and an inner wall of the opening in an extension direction of the first signal line is defined as a first distance, a distance in the second direction between the second signal electrode and the first portion is defined as a second distance, and a distance between the first signal electrode and the inner wall of the opening in a direction perpendicular to the first direction and the extension direction of the first signal line is defined as a third distance, the third distance is greater than half the second distance, greater than the first distance, and less than twice the second distance.
(Item 6) In the substrate connection structure according to Item 1 or 2, the first ground electrode has an opening that opens so as to surround the first signal electrode when viewed in the first direction. The substrate connection structure further includes a specific portion that extends in the first direction from the inner wall of the opening toward an imaginary line at a position where the imaginary line overlaps the inner wall of the opening when viewed in the first direction when the imaginary line is drawn from the first signal line in the extension direction of the first signal line. A distance in the second direction between the first signal electrode and the specific portion is substantially equal to a distance in the second direction between the second signal electrode and the first portion.
(Item 7) In the substrate connection structure according to Item 1 or 2, the first ground electrode has an opening that opens so as to surround the first signal electrode when viewed in the first direction. A plurality of a combination of the first signal line, the first signal electrode, and the opening are disposed side by side along the opposing surface of the first substrate.
(Item 8) An antenna device according to the present disclosure includes the substrate connection structure according to any one of Items 1 to 7.

(Item 9) A communication device according to the present disclosure includes the substrate connection structure or antenna device according to any one of Items 1 to 8.

### REFERENCE SIGNS LIST

10 communication device, 100 antenna module, 111A to 113D, 117 switch, 112AR to 112DR low-noise amplifier, 112AT to 112DT power amplifier, 114A to 114D attenuator, 115A to 115D phase shifter, 116 divider, 118 mixer, 119 amplifier circuit, 120 antenna device, 121 radiating element, 130, 130A, 130B, 130C, 130D, 130E dielectric substrate (connection structure), 131, 131A, 131B first substrate, 131a opposing surface, 131b main surface, 132 second substrate, 132a first main surface, 132b second main surface, 132c side surface, 140 feed wiring, 141 first signal line, 142 second signal line, 150, 150B opening, 161 first portion, 162 second portion, 163 third portion, 170, 183 connection conductor, 181 first pad, 182 second pad, 200 specific portion, 201 imaginary line, C1, C2 solder bump, E1, E1B, E1D first signal electrode, E2, E2E, E2B second signal electrode, GND1, GND1A, GND1B first ground electrode, GND2, GND2E, GND2A second ground electrode.

1. A substrate connection structure comprising:
a first substrate; and
a second substrate having a main surface and a side surface that intersect each other,
wherein the first substrate includes
an opposing surface facing the side surface of the second substrate,
a first signal line disposed opposite the opposing surface,
a plate-shaped first ground electrode that is disposed on the opposing surface or that is disposed opposite the opposing surface at a position between the opposing surface and the first signal line, and
a first signal electrode connected to the first signal line and exposed on the opposing surface,
the second substrate includes
a second signal line disposed opposite the main surface,
a plate-shaped second ground electrode disposed opposite the main surface at a position between the main surface and the second signal line, and
a second signal electrode connected to the second signal line, and exposed on the side surface and connected to the first signal electrode,
the first ground electrode is configured to sandwich the first signal electrode from at least two directions when viewed in a first direction that is a normal direction of the opposing surface,
the second ground electrode includes
a first portion connected to the first ground electrode, and
a second portion connected to the first portion,
when viewed in a second direction that is a normal direction of the main surface, at least part of the first portion overlaps the second signal electrode, and the second portion does not overlap the second signal electrode, and
a distance in the second direction between the second signal electrode and the first portion is greater than a distance in the second direction between the second signal line and the second portion.

2. The substrate connection structure according to claim 1,
wherein a size of the second signal electrode in the second direction is larger than a size of the second signal line in the second direction.

3. The substrate connection structure according to claim 1,
wherein the second ground electrode further includes
a connection conductor extending in the second direction and connecting the first portion to the second portion, and
a third portion extending in the first direction from a connection portion between the connection conductor and the second portion, and
a distance in the first direction between the connection conductor and the second signal electrode is greater than a size of the connection conductor in the first direction.

4. The substrate connection structure according to claim 1,
wherein the second signal electrode has a rectangular parallelepiped shape or a semi-cylindrical shape.

5. The substrate connection structure according to claim 1,
wherein the first ground electrode has an opening that opens so as to surround the first signal electrode when viewed in the first direction, and
when a shortest distance between the first signal electrode and an inner wall of the opening in an extension direction of the first signal line is defined as a first distance, a distance between the second signal electrode and the first portion in the second direction is defined as a second distance, and a distance between the first signal electrode and the inner wall of the opening in a direction perpendicular to the first direction and the extension direction of the first signal line is defined as a third distance,
the third distance is greater than half the second distance, greater than the first distance, and less than twice the second distance.

6. The substrate connection structure according to claim 1,
wherein the first ground electrode has an opening that opens so as to surround the first signal electrode when viewed in the first direction, and
further includes a specific portion extending in the first direction from an inner wall of the opening toward an imaginary line at a position where the imaginary line overlaps the inner wall of the opening when viewed in the first direction when the imaginary line is drawn from the first signal line in an extension direction of the first signal line, and
a distance in the second direction between the first signal electrode and the specific portion is substantially equal to a distance in the second direction between the second signal electrode and the first portion.

7. The substrate connection structure according to claim 1,
wherein the first ground electrode has an opening that opens so as to surround the first signal electrode when viewed in the first direction, and
a plurality of a combination of the first signal line, the first signal electrode, and the opening are disposed side by side along the opposing surface of the first substrate.

8. The substrate connection structure according to claim 1, wherein the first signal electrode is connected to the second signal electrode via a first solder bump, and the first ground electrode is connected to the first portion of the second ground electrode via a second solder bump.

9. The substrate connection structure according to claim 1, wherein the first ground electrode is disposed on the opposing surface of the first substrate.

10. The substrate connection structure according to claim 1, wherein the second ground electrode further includes a connection conductor connecting the first portion to the second portion.

11. The substrate connection structure according to claim 1, wherein the first signal electrode includes a first pad connected to the first signal line, a second pad exposed on the opposing surface, and a connection conductor connecting the first pad and the second pad.

12. The substrate connection structure according to claim 1, wherein the first ground electrode is configured to sandwich the first signal electrode from three directions when viewed in the first direction.

13. The substrate connection structure according to claim 12, wherein the first ground electrode is configured to sandwich the first signal electrode from four directions when viewed in the first direction.

14. The substrate connection structure according to claim 1, wherein the first substrate and the second substrate are formed of different dielectric materials.

15. An antenna device comprising:
the substrate connection structure according to claim

1.

16. The antenna device according to claim 15, further comprising:
a plurality of radiating elements disposed on the main surface of the second substrate,
wherein the first signal line and the second signal line form part of a feed wiring configured to supply a signal to at least one of the plurality of radiating elements.

17. A communication device comprising:
the substrate connection structure according to claim 1.

18. The communication device according to claim 17, further comprising a radio frequency integrated circuit (RFIC) mounted on the first substrate, wherein the first signal line is configured to electrically couple the RFIC to the first signal electrode.
